(19) United States
(12) Patent Application Publication
(10) Pub. No.: US 2026/0316222 A1
(43) Pub. Date: Oct. 15, 2026

(54) ELECTROCHEMICAL MECHANICAL POLISHING APPARATUS

(71) Applicant: SAMSUNG ELECTRONICS CO., LTD., Suwon-si (KR)

(72) Inventors: Donggeon KIM, Suwon-si (KR); Donghoon KWON, Suwon-si (KR)

(73) Assignee: SAMSUNG ELECTRONICS CO., LTD., Suwon-si (KR)

(21) Appl. No.: 19/374,741

(22) Filed: Oct. 30, 2025

(30) Foreign Application Priority Data
Apr. 14, 2025 (KR) 10-2025-0048284

(51) Int. Cl. B24B 57/02; B24B 37/10; B24B 37/32

(52) U.S. Cl. CPC B24B 57/02; B24B 37/107; B24B 37/32

(57) ABSTRACT

An electrochemical mechanical polishing apparatus, includes a plate; a polishing pad disposed above the platen, and including a first pad portion having a groove formed concavely inwardly on an upper surface thereof, a conductive portion formed of a conductive material, and a non-conductive portion formed of a non-conductive material, and a second pad portion disposed below the first pad portion and including a conductive material; a polishing head including a retainer ring supporting a wafer and including a conductive material, and disposed above the polishing pad to press the wafer; and an electrode disposed below the polishing pad, and connected to the second pad portion.

### CROSS-REFERENCE TO RELATED APPLICATION(S)

This application claims the benefit under 35 USC 119(a) of Korean Patent Application No. 10-2025-0048284 filed on Apr. 14, 2025 in the Korean Intellectual Property Office, the entire disclosure of which is incorporated herein by reference for all purposes.

### BACKGROUND

The present inventive concept relates to an electrochemical mechanical polishing apparatus.

In general, a Chemical Mechanical Planarization (CMP) process used in a process of polishing a semiconductor wafer is also known as a chemical mechanical planarization process. In the CMP process, an apparatus, which mechanically polishes the semiconductor wafer by mutual rotational movement while a polishing head having a wafer attached thereon is pressed at a certain pressure, in a polishing pad attached to a platen, and at the same time, chemically polishes the semiconductor wafer by injecting abrasive particles and a chemical solution reacting a metal surface, is used.

However, during the CMP process, the polishing head physically holds the wafer and performs the process. To this end, high air pressure should be applied to a retainer ring of the polishing head, and therefore, a pad rebound phenomenon may occur at an edge portion of the wafer, and furthermore, there may a problem in that it is difficult to control a removal rate at the edge portion of the wafer.

Recently, an Electrochemical Mechanical Planarization (ECMP) process has been introduced. A basic configuration of the ECMP apparatus is the same as that of the CMP, but in a state in which a cathode is provided on the plate, and an anode is provided on the wafer, a conductive polishing pad is used as a polishing pad and an electrolyte is injected between the wafer and the conductive polishing pad, an electrochemical reaction occurs between the electrode and the electrolyte, so that a metal surface of the wafer is changed into a surface which is easy to be electrochemically polished, and at the same time, the metal surface having been electrochemically changed is mechanically polished by the pressing force and rotation applied by the polishing head. Therefore, it has the characteristic of excellent polishing efficiency even at a low polishing pressure.

In this case, there is a need for the development of an ECMP apparatus that can control the slurry by improving electric field controllability, eliminate the pad rebound phenomenon at the edge portion of the wafer, and control the edge portion removal rate, thereby more effectively improving the problems of the CMP process as described above.

### SUMMARY

An aspect of the present inventive concept is to provide an electrochemical mechanical polishing apparatus for effectively controlling a flow of slurry supplied to a polishing pad.

An aspect of the present inventive concept is to provide an electrochemical mechanical polishing apparatus for reducing a rebound phenomenon at an edge portion of a wafer by sufficiently and evenly supplying slurry supplied to the polishing pad to the edge portion of the wafer.

According to an aspect of the present inventive concept, an electrochemical mechanical polishing apparatus may include a platen, a polishing pad disposed above the platen, and including a first pad portion having a groove formed concavely inwardly on an upper surface thereof, a conductive portion formed of a conductive material, and a non-conductive portion formed of a non-conductive material, and a second pad portion disposed below the first pad portion and including a conductive material, a polishing head including a retainer ring supporting a wafer and including a conductive material, and disposed above the polishing pad to press the wafer, and an electrode disposed below the polishing pad and connected to the second pad portion.

According to another aspect of the present inventive concept, an electrochemical mechanical polishing apparatus may include a platen, a polishing pad disposed above the platen, and including a first pad portion including a groove formed concavely inwardly on an upper surface thereof, and formed of a conductive material, and a second pad portion disposed below the first pad portion, and formed of a conductive material, a polishing head including a retainer ring supporting a wafer and including a conductive material, and disposed above the polishing pad to press the wafer, and an electrode disposed between the platen and the polishing pad and connected to the second pad portion.

According to another aspect of the present inventive concept, an electrochemical mechanical polishing apparatus may include a platen, a polishing pad disposed above the platen, and including a first pad portion including a groove formed concavely inwardly on an upper surface thereof and including a conductive material, and a second pad portion disposed below the first pad portion and including a non-conductive material, a polishing head including a retainer ring supporting a wafer and including a conductive material, and disposed above the polishing pad to press the wafer, and an electrode connected to the first pad portion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a perspective view illustrating an electrochemical mechanical polishing apparatus according to an example embodiment of the present inventive concept;

FIG. 2 illustrates the electrochemical mechanical polishing apparatus of FIG. 1 viewed from above;

FIG. 3A is a cross-sectional view illustrating an electrochemical mechanical polishing apparatus according to an example embodiment of the present inventive concept viewed from the direction, taken along line I-I’ of FIG. 1;

FIG. 3B is a cross-sectional view illustrating an electrochemical mechanical polishing apparatus according to another embodiment of the present inventive concept viewed from the direction, taken along line I-I’ of FIG. 1;

FIGS. 4A and 4B are cross-sectional views illustrating a retainer ring according to example embodiments of the present inventive concept viewed from the direction, taken along line II’-II’ of FIG. 3A;

FIG. 5A is a cross-sectional view illustrating a polishing pad of an electrochemical mechanical polishing apparatus according to another embodiment of the present inventive concept viewed from the direction, taken along line I-I’ of FIGS. 1 and 5B is a plan view illustrating a polishing pad thereof viewed from above;

FIG. 6A is a cross-sectional view illustrating a polishing pad of an electrochemical mechanical polishing apparatus according to another embodiment of the present inventive concept viewed from the direction, taken along line I-I’ of FIGS. 1 and 6B is a plan view illustrating a polishing pad thereof viewed from above;

FIG. 7A is a cross-sectional view illustrating a polishing pad of an electrochemical mechanical polishing apparatus according to another embodiment of the present inventive concept viewed from the direction, taken along line I-I’ of FIGS. 1 and 7B is a plan view thereof viewed from above;

FIG. 8A is a cross-sectional view illustrating a polishing pad of an electrochemical mechanical polishing apparatus according to another embodiment of the present inventive concept viewed from the direction, taken along line I-I’ of FIGS. 1 and 8B is a plan view thereof viewed from above;

FIG. 9A is a cross-sectional view illustrating a polishing pad of an electrochemical mechanical polishing apparatus according to another embodiment of the present inventive concept viewed from the direction, taken along line I-I’ of FIGS. 1 and 9B is a plan view illustrating a polishing pad thereof viewed from above;

FIG. 10A is a cross-sectional view illustrating a polishing pad of an electrochemical mechanical polishing apparatus according to another embodiment of the present inventive concept viewed from the direction, taken along line I-I’ of FIGS. 1 and 10B is a plan view illustrating a polishing pad thereof viewed from above;

FIG. 11A is a cross-sectional view illustrating a polishing pad of an electrochemical mechanical polishing apparatus according to another embodiment of the present inventive concept viewed from the direction, taken along line I-I’ of FIGS. 1 and 11B is a plan view illustrating a polishing pad thereof viewed from above;

FIG. 12A is a cross-sectional view illustrating a polishing pad of an electrochemical mechanical polishing apparatus according to another embodiment of the present inventive concept viewed from the direction, taken along line I-I’ of FIGS. 1 and 12B is a plan view illustrating a polishing pad thereof viewed from above;

FIGS. 13A and 13B are cross-sectional views illustrating a polishing pad of an electrochemical mechanical polishing apparatus according to other embodiments of the present inventive concept viewed from the direction, taken along line I-I’ of FIG. 1;

FIG. 14A is a cross-sectional view illustrating an electrochemical mechanical polishing apparatus including an electrode according to example embodiments of the present inventive concept viewed from the direction, taken along line I-I’ of FIGS. 1 and 14B is a plan view illustrating a polishing pad thereof viewed from above;

FIG. 14C is a cross-sectional view illustrating an electrochemical mechanical polishing apparatus including an electrode according to other embodiments of the present inventive concept viewed from the direction, taken along line I-I’ of FIGS. 1, 14D and 14E are plan views illustrating a polishing pad thereof viewed from above;

FIG. 14F is a cross-sectional view illustrating an electrochemical mechanical polishing apparatus including an electrode according to other embodiments of the present inventive concept viewed from the direction, taken along line I-I’ of FIGS. 1, 14G and 14H are plan views illustrating a polishing pad thereof viewed from above;

FIG. 15A is a cross-sectional view illustrating an electrochemical mechanical polishing apparatus including an electrode according to other embodiments of the present inventive concept viewed from the direction, taken along line I-I’ of FIGS. 1 and 15B is a plan view illustrating a polishing pad thereof viewed from above;

FIG. 15C is a cross-sectional view illustrating an electrochemical mechanical polishing apparatus including an electrode according to other embodiments of the present inventive concept viewed from the direction, taken along line I-I’ of FIGS. 1, 15D and 15E are plan views illustrating a polishing pad thereof viewed from above;

FIG. 15F is a cross-sectional view illustrating an electrochemical mechanical polishing apparatus including an electrode according to other embodiments of the present inventive concept viewed from the direction, taken along line I-I’ of FIGS. 1 , 15G and 15H are plan views illustrating a polishing pad thereof viewed from above;

FIG. 16A is a cross-sectional view illustrating an electrochemical mechanical polishing apparatus including an electrode according to other embodiments of the present inventive concept viewed from the direction, taken along line I-I’ of FIGS. 1 and 16B is a plan view illustrating a polishing pad thereof viewed from above;

FIG. 16C is a cross-sectional view illustrating an electrochemical mechanical polishing apparatus including an electrode according to other embodiments of the present inventive concept viewed from the direction, taken along line I-I’ of FIGS. 1, 16D and 16E are plan views illustrating a polishing pad thereof viewed from above; and

FIG. 16F is a cross-sectional view illustrating an electrochemical mechanical polishing apparatus including an electrode according to other embodiments of the present inventive concept viewed from the direction, taken along line I-I’ of FIGS. 1, 16G and 16H are plan views illustrating a polishing pad thereof viewed from above.

### DETAILED DESCRIPTION

Hereinafter, preferred example embodiments of the present inventive concept will be described with reference to the attached drawings.

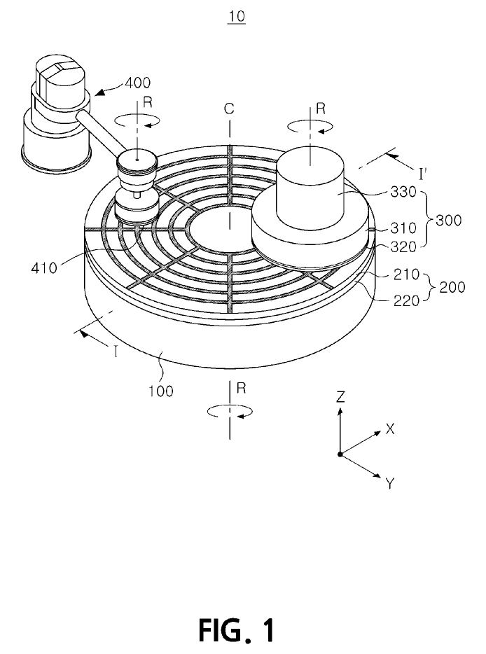

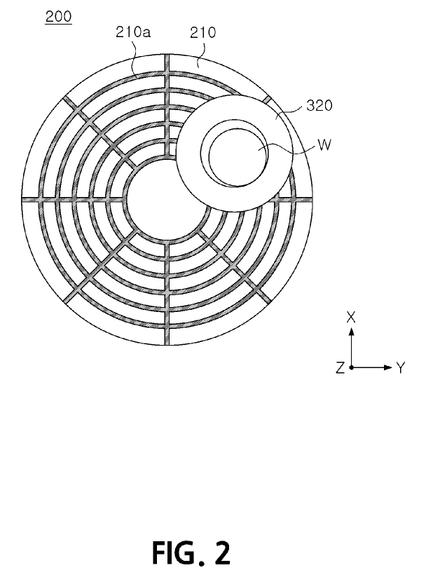

FIG. 1 is a perspective view illustrating an electrochemical mechanical polishing apparatus according to an example embodiment of the present inventive concept. FIG. 2 illustrates the electrochemical mechanical polishing apparatus of FIG. 1 viewed from above.

Referring to FIGS. 1 and 2, an electrochemical mechanical polishing apparatus 10 may be an apparatus for performing an Electrochemical Mechanical Planarization (ECMP) process on a wafer W. In this case, the electrochemical mechanical polishing apparatus 10 may include a platen 100, a polishing pad 200, a polishing head 300, and an electrode 500. In addition, the electrochemical mechanical polishing apparatus 10 may further include a conditioning module 400 and a slurry supply unit (not shown).

The platen 100 may be rotatably installed on a rotation axis (not shown). The platen 100 may have a circular plate shape in an upper end thereof. The platen 100 may be driven to rotate in a predetermined rotation direction (R) by the rotation axis. The platen 100 may be rotated, for example, clockwise, but an example embodiment thereof is not limited thereto. A polishing pad 200 may be disposed on an upper surface of the platen 100.

The polishing pad 200 may perform mechanical polishing on a wafer W by directly contacting a surface of the wafer W. In this case, the polishing pad 200 may include a first pad portion 210 and a second pad portion 220.

The first pad portion 210 may be in contact with the surface of the wafer W. A polishing layer (not shown) for polishing the wafer W may be provided on an upper surface of the first pad portion 210.

In addition, a groove 210a may be provided on the upper surface of the first pad portion 210. The groove 210a may be a passage for smoothly discharging a treatment solution such as slurry S supplied to a surface of the polishing pad 200.

The groove 210a may be formed to have a concave shape from the upper surface of the first pad portion 210 inwardly of the first pad portion 210. More specifically, the groove 210a may be formed to extend downwardly (in -Z direction) based on the upper surface of the first pad portion 210. In this case, the groove 210a may have a predetermined depth (L).

In addition, the groove 210a may be formed on the entire upper surface of the first pad portion 210. For example, the groove 210a may extend in various directions from a center of the first pad portion 210 outwardly in a radial direction on the upper surface of the first pad portion 210. The groove 210a may have, for example, a radial shape, but an example embodiment thereof is not limited thereto.

The first pad portion 210 may be stacked and disposed on the second pad portion 220. More specifically, the second pad portion 220 may be coupled to an upper surface of the platen 100. The first pad portion 210 may be coupled to the upper surface of the second pad portion 220.

The first pad portion 210 and the second pad portion 220 may have various shapes. For example, the first pad portion 210 and the second pad portion 220 may be provided in a circular plate shape having the same or similar diameter. The first pad portion 210 and the second pad portion 220 may at least partially include a conductive material, to be described later.

The polishing head 300 may be disposed above the platen 100 to bring the wafer W into contact with the polishing pad 200. In this case, the polishing head 300 may include a head portion 310 and a retainer ring 320.

The retainer ring 320 may be connected to a lower end portion of the head portion 310. The retainer ring 320 may be provided to protrude downwardly (in -Z direction) from a lower surface of the head portion 310. The wafer W may be accommodated and supported within the retainer ring 320.

The polishing head 300 may be rotated in a certain direction by a rotation axis 330 and a driving unit (not shown) connected thereto. The polishing head 300 may be rotated in the same rotational direction (R) as the platen 100, for example, but an example embodiment thereof is not limited thereto.

The wafer W may be supported by the lower surface of the head portion 310 and the retainer ring 320, and may be rotated together with the polishing head 300 when it rotates and may be brought into contact with the polishing pad 200. As described above, mechanical polishing may be performed while the wafer W is brought into contact with the polishing pad 200.

Meanwhile, the polishing head 300 may further include a moving portion (not shown) connected to the rotation shaft 330. By the moving portion, the polishing head 300 may be moved between an upper portion and an outer side of the platen 100. In addition, a vacuum line (not shown) is provided in the moving portion, and when the polishing head 300 moves, the wafer W may be adsorbed and fixed. In addition, the moving portion may be configured to be able to swing with a predetermined rotation radius around the rotation axis. Accordingly, the polishing head 300 may rotate on its own, and at the same time, swing by the moving portion, and an ECMP process can be performed.

A slurry supply unit (not shown) may supply slurry S to the polishing pad 200. The slurry S may be supplied to an upper surface of the polishing pad 200. Using the slurry S supplied from the slurry supply unit, electrochemical mechanical polishing may be performed on the wafer W.

For example, the slurry supply unit may be disposed above the platen 100. The slurry supply unit may be disposed between the polishing head 300 and a conditioning module 400 to discharge the slurry S onto the upper surface of the polishing pad 200. In this case, the polishing head 300, the conditioning module 400, and the slurry supply unit may be sequentially disposed in the rotation direction (R) of the platen 100. Accordingly, the slurry S supplied from the slurry supply unit may be more smoothly provided to the polishing head 300.

As another example, the slurry supply unit may be disposed below the polishing pad 200. In this case, the polishing pad 200 may be provided with a discharge port (not shown) for discharging the slurry S supplied from the slurry supply unit to the upper surface of the polishing pad 200. The slurry S discharged through the discharge port is supplied to the surface of the wafer W, thereby performing the above-described electrochemical mechanical polishing process (ECMP process).

The conditioning module 400 may perform a role of conditioning a surface condition of the polishing pad 200. The conditioning module 400 may polish the surface of the polishing pad 200 to maintain surface roughness of the polishing pad 200 in a constant state. To this end, the conditioning module 400 may be provided with a disk 410 being in contact with the polishing pad 200.

For example, the conditioning module 400 may polish the polishing pad 200 while the polishing of the wafer W is performed by the polishing head 300. As another example, the conditioning module 400 may polish the polishing pad 200 while the polishing of the wafer W is stopped. Using such methods, the conditioning module 400 may restore or maintain the surface roughness of the polishing pad 200.

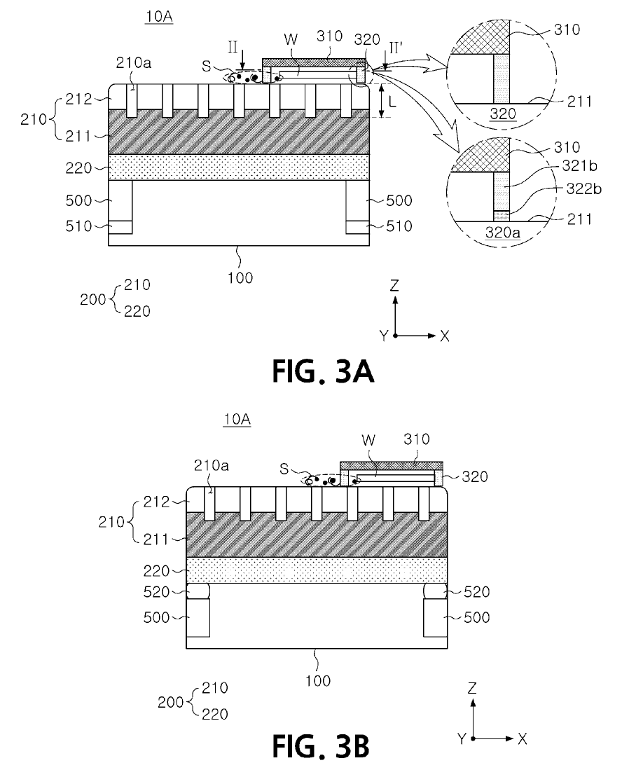

FIG. 3A is a cross-sectional view illustrating an electrochemical mechanical polishing apparatus according to an example embodiment of the present inventive concept viewed from the direction, taken along line I-I’ of FIG. 1. FIG. 3B is a cross-sectional view illustrating an electrochemical mechanical polishing apparatus according to another embodiment of the present inventive concept viewed from the direction, taken along line I-I’ of FIG. 1.

Referring to FIG. 3A, in the case of an electrochemical mechanical polishing apparatus 10A according to an example embodiment of the present inventive concept (hereinafter, Example 1), a first pad portion 210 of a polishing pad 200 may include a conductive portion 211 formed of a conductive material and a non-conductive portion 212 formed of a non-conductive material. In this case, other features of the electrochemical mechanical polishing apparatus 10A are the same or similar to those described above, so a duplicate description thereof is omitted.

For example, the conductive portion 211 may include nano (nm) sized-glassy carbon particles. Hereinafter, for convenience of explanation, the description will be focus on the case in which the conductive material included in the polishing pad 300 is glassy carbon, but it is obvious that the present inventive concept is not limited thereto. In the case of Example 1, glassy carbon particles may be evenly included throughout the conductive portion 211. More specifically, when viewed from above the polishing pad 200, the first pad portion 210 may have a form in which the glassy carbon particles are uniformly included throughout.

For example, the non-conductive portion 212 may be formed of a non-conductive and wear-resistant material such as polyurethane.

The conductive portion 211 may be disposed at least partially below a groove 210a. The non-conductive portion 212 may be disposed on the conductive portion 211.

For example, based on a height direction (e.g., Z) of the polishing pad 200, the conductive portion 211 may be formed to extend from a lower end portion of the groove 210a to a bottom surface of the first pad portion 210 in a downward direction (in -Z direction). As another example, although not shown in the drawing, the conductive portion 211 may be formed to extend from directly below the groove 210a in the downward direction (in -Z direction) to the bottom surface of the first pad portion 210.

The non-conductive portion 212 may be formed to extend from the upper end of the conductive portion 211 to an upper surface of the first pad portion 210 (i.e., an upper surface of the polishing pad 200) in an upward direction (in +Z direction). That is, the groove 210a may be formed in the non-conductive portion 212. In this case, based on the height direction (Z) described above, the conductive portion 211 may be formed to have a thickness greater than the non-conductive portion 212, but the present inventive concept is not limited thereto.

Accordingly, based on a boundary line with which the conductive portion 211 and the non-conductive portion 212 are in contact, in the polishing pad 200, an upper portion of the boundary line may be formed of a non-conductive material, and a lower portion of the boundary line may be formed of a conductive material. In addition, the upper surface of the polishing pad 200 in contact with the wafer W may also be formed of a non-conductive material.

In addition, the second pad portion 220 may include a conductive material. For example, the second pad portion 220, like the first pad portion 210, may include glassy carbon particles of nano size evenly throughout the entire surface. More specifically, when viewed from above the polishing pad 200, the second pad portion 220 may include glassy carbon particles uniformly distributed throughout the entire surface.

In the above case, a concentration of glassy carbon included in the conductive portion 211 may be the same as a concentration of glassy carbon included in the second pad portion 220. However, the present inventive concept is not limited thereto, and the conductive portion 211 may include glassy carbon at a higher concentration than the second pad portion 220, or the second pad portion 220 may include glassy carbon at a higher concentration than the conductive portion 211.

In Example 1, an electrode 500 may be disposed below the polishing pad 200, and may be connected to a cathode of a power supply unit (not shown). For example, the electrode 500 may be disposed in an embedded form in an upper end portion of the platen 100. In this case, an upper end portion of the electrode 500 may be fixedly coupled to the lower surface of the second pad portion 220 through an opening (not shown) provided on the upper surface of the platen 100. Since the second pad portion 220 includes a conductive material, the electrode 500 may be electrically connected to the second pad portion 220.

Meanwhile, as another example, although not shown in the drawing, the electrode 500 may be disposed between the platen 100 and the polishing pad 200. In this case, the upper end portion of the electrode 500 may be coupled to the polishing pad 200, and the lower end portion of the electrode 500 may be coupled to the upper end of the platen 100.

In addition, the retainer ring 320 may have an electrode (not shown), so that the electrode may be connected to an anode of the power supply unit. Slurry S supplied to the polishing pad 200 includes an electrolyte, and an electrochemical mechanical polishing (ECMP) process may be performed by applying current and voltage to the slurry S through the above-described electrodes. In this case, the properties of the slurry S change depending on the type of electrolyte, and the ECMP process can be controlled by adjusting the voltage and current supplied from the power supply unit to change the electrochemical reactivity between the slurry S and a surface of the wafer W.

A first rotating portion 510 may be disposed in a lower end portion of the electrode 500. The first rotating portion 510 may be disposed between the lower end portion of the electrode 500 and the platen 100, and may be configured to rotate independently when the platen 100 rotates. The first rotating portion 510 may be, for example, a slip ring.

Alternatively, FIG. 3B discloses an exemplary embodiment disclosing a second rotating portion 520, instead of the first rotating portion 510. The second rotating portion 520 may be disposed in an upper end portion of the electrode 500. The second rotating portion 520 may be disposed between the upper end portion of the electrode 500 and the polishing pad 200, and may be configured to rotate independently when the platen 100 rotates. The second rotating portion 520 may be configured as, for example, a roller.

As described above, by installing the first rotating portion 510 or the second rotating portion 520 on the electrode 500, when the platen 100 rotates, a wire (not shown) connected to the electrode 500 by the first rotating portion 510 may be prevented from being twisted or tangled.

Referring back to FIG. 3A, the retainer ring 320 may include a conductive material. For example, as shown in the enlarged view on the upper right side of FIG. 3A, the retainer ring 320 (hereinafter, referred to as a first retainer ring) may be formed of a composite material including two different types of materials. Such a composite material may include a ‘thermoplastic plastic material’ having high thermal and chemical stability and wear resistance, and a ‘conductive material’ having excellent conductivity.

For example, the first retainer ring 320 may be manufactured by blending a conductive polymer into Polyphenylene Sulfide (PPS) or Polyether Ether Ketone (PEEK). As described above, the first retainer ring 320 may be formed of a composite material including a thermoplastic plastic material and a conductive material. Thereby, since the first retainer ring 320 includes a conductive material, when current and voltage are applied through the electrode 500 during the ECMP process, an electric field may be generated in the retainer ring 320. In this case, by controlling the electric field generated in the first retainer ring 320 through adjustment of the applied current and voltage, a flow of the slurry S may be effectively controlled so that the slurry S flows into the first retainer ring 320 or is discharged from the first retainer ring 320. In addition, since the first retainer ring 320 includes a thermoplastic plastic material having excellent wear resistance, damage such as wear due to friction may be minimized during the ECMP process.

As another example, as shown in the enlarged view on the upper lower side of FIG. 3A, the retainer ring 320a (hereinafter, referred to as a second retainer ring) may be formed of two layers separated from each other. More specifically, an upper end portion 321b of the second retainer ring 320a may be formed of a conductive polymer material, and a lower end portion 322b thereof may be made of PPS or PEEK. That is, the lower end portion 322b of the second retainer ring 320a, in contact with the polishing pad 200 may be formed of a material with excellent wear resistance, and the upper end portion 321b of the second retainer ring 320a, which is the other portion, may be formed of a material with excellent conductivity. Thereby, the second retainer ring 320a may minimize damage such as wear due to friction during the ECMP process, and can effectively control the flow of the slurry S through the generation and control of an electric field.

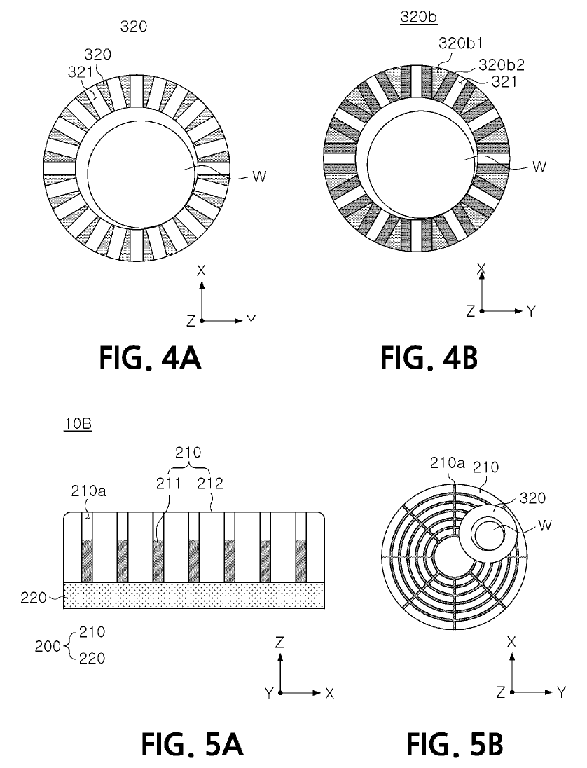

FIGS. 4A and 4B are cross-sectional views illustrating a retainer ring according to example embodiments of the present inventive concept viewed from the direction, taken along line II’-II’ of FIG. 3A.

Referring to FIG. 4, the first retainer ring 320 may include a flow path unit 321 for the slurry S to flow. The flow path unit 321 may extend in a radial direction of the first retainer ring 320, and may have a form partially penetrating a side wall of the first retainer ring 320. The flow path unit 321 may be provided in plural. The plurality of flow path units 321 may be disposed to be spaced apart from each other in a circumferential direction of the first retainer ring 320. In this case, the flow path units 321 may have the same or similar sizes. Meanwhile, although not shown in the drawing, the second retainer ring 320a may also be provided in a form including a plurality of flow path units 321, similar to that of the first retainer ring 320.

Referring to FIG. 4B, the retainer ring 320b (hereinafter, referred to as a third retainer ring) may include both the features of the first retainer ring 320 and the second retainer ring 320. Hereinafter, in the third retainer ring 320b, a portion in which PPS or PEEK and a conductive polymer are mixed, like the first retainer ring 320, is referred to as ‘a first retainer ring portion 320b1’. In the third retainer ring 320b, a lower end portion thereof is formed of PPS or PEEK, like the second retainer ring 320, but an upper end portion thereof is formed of a conductive polymer, which is referred to as ‘a second retainer ring portion 320b2’.

In addition, the third retainer ring 320b may include a plurality of flow path units 321. For example, third retainer ring 320b may have a form in which the first retainer ring 320b1, the second retainer ring portion 320b2, and the flow path portion 321 are sequentially and repeatedly disposed in the circumferential direction thereof.

In the above case, during the ECMP process, slurry S may be introduced into the retaining ring (320, 320a, 320b) through the flow path portion 321, so that the slurry S may be supplied to the surface of the wafer W accommodated and supported within the retaining ring (320, 320a, 320b). In addition, the slurry S that was introduced into the retainer ring (320, 320a, 320b) may be discharged to the outside of the retainer ring (320, 320a, 320b) through the flow path portion 321. In this case, the flow of the slurry S introduced or discharged through the flow path portion 321 may be controlled through the generation and control of a magnetic field in the retainer ring (320, 320a, 320b) as described above.

FIG. 5A is a cross-sectional view illustrating a polishing pad of an electrochemical mechanical polishing apparatus according to another embodiment of the present inventive concept viewed from the direction, taken along line I-I’ of FIGS. 1 and 5B is a plan view illustrating a polishing pad thereof viewed from above.

Referring to FIGS. 5A and 5B, in the case of an electrochemical mechanical polishing apparatus 10B according to another embodiment of the present inventive concept (hereinafter, Example 2), a first pad portion 210 of the polishing pad 200 may include a conductive portion 211 and a non-conductive portion 212. In addition, a second pad portion 220 may be formed of a conductive material. In this case, most of the features of the electrochemical mechanical polishing apparatus 10B are the same or similar to similar to those of Example 1 described above, so redundant descriptions thereof will be omitted and descriptions thereof will be provided, focusing on differences thereof.

The conductive portion 211 may be disposed below a groove 210a. More specifically, the conductive portion 211 may extend from directly below the groove 210a to a bottom surface of the first pad portion 210 in a downward direction (in -Z direction). As described above, since the conductive portion 211 is formed in a region directly below the groove 210a, when viewed from above the polishing pad 200, the conductive portion 211 may overlap with the groove 210a.

A non-conductive portion 212 may be formed in a region of the first pad portion 210 in which the groove 210a is not disposed. Accordingly, as shown in FIG. 5A, when based on a cross-sectional view viewed in a side direction (e.g., in Z-X plane direction) of the polishing pad 200, the conductive portion 211 and the non-conductive portion 212 may be alternately disposed in the width (w) direction of the polishing pad 200. In this case, the conductive portion 211 has the same width as the groove 210a, so the conductive portion 211 may have a smaller width than the non-conductive portion 212.

In addition, since the non-conductive portion 212 is formed to overlap with the groove 210a as described above, when the polishing pad 200 is viewed from above, only the groove 210a and the non-conductive portion 212 may be disposed on the upper surface of the polishing pad 200 as shown in FIG. 5B.

In the case of Example 2, a concentration of glassy carbon included in the conductive portion 211 may be lower than or equal to a concentration of glassy carbon included in the second pad portion 220, or the conductive portion 211 may include glassy carbon at a higher concentration than the second pad portion 220, which is the same as described above.

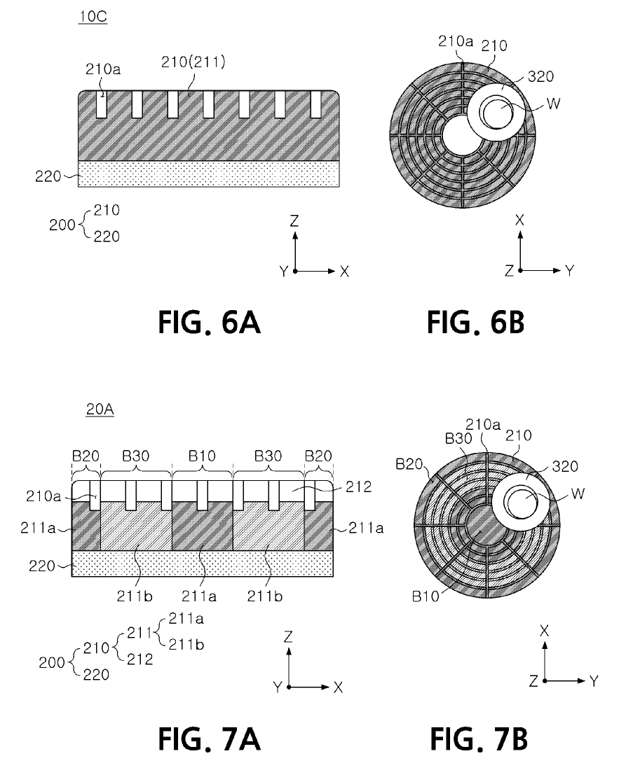

FIG. 6A is a cross-sectional view illustrating a polishing pad of an electrochemical mechanical polishing apparatus according to another embodiment of the present inventive concept viewed from the direction, taken along line I-I’ of FIGS. 1 and 6B is a plan view illustrating a polishing pad thereof viewed from above.

Referring to FIGS. 6A and 6B, in the case of an electrochemical mechanical polishing apparatus 10C according to another embodiment of the present inventive concept (hereinafter, Example 3), a first pad portion 210 of a polishing pad 200 may include only a conductive portion 211. That is, the first pad portion 210 may not include a non-conductive portion 212. In this case, most of the features of the electrochemical mechanical polishing apparatus 10C are the same or similar to those of Example 1 described above, so redundant descriptions thereof will be omitted and descriptions thereof will be provided, focusing on differences thereof.

In the case of Example 3, the first pad portion 210 may be formed entirely of a conductive material. In addition, glassy carbon particles, which are conductive particles, may be uniformly included throughout in the first pad portion 210. Accordingly, as shown in FIGS. 6A and 6B, the first pad portion 210 may have a form in which nano-sized glassy carbon particles are uniformly included throughout when viewed in a side direction (e.g., in Z-X plane direction) and when viewed from above the polishing pad 200.

In addition, a second pad portion 220 may be formed of a conductive material. In this case, a concentration of the glassy carbon included in the conductive portion 211 may be lower than or equal to a concentration of the glassy carbon included in the second pad portion 220, or glassy carbon may be included in the conductive portion 211 at a higher concentration than the second pad portion 220, which is the same as in the above-described Examples 1 and 2.

FIG. 7A is a cross-sectional view illustrating a polishing pad of an electrochemical mechanical polishing apparatus according to another embodiment of the present inventive concept viewed from the direction, taken along line I-I’ of FIGS. 1 and 7B is a plan view illustrating a polishing pad thereof viewed from above.

Referring to FIGS. 7A and 7B, in the case of an electrochemical mechanical polishing apparatus 20A according to another embodiment of the present inventive concept (hereinafter, Example 4), a first pad portion of a polishing pad 200 may include a conductive portion 211 and a non-conductive portion 212. In addition, a second pad portion 220 may be formed of a conductive material. In this case, most of the features of the electrochemical mechanical polishing apparatus 20A are the same or similar to those of Example 1 described above, so redundant descriptions thereof will be omitted and descriptions thereof will be provided focusing on differences thereof.

The conductive portion 211 according to Example 4 may be disposed below a groove 210a. The conductive portion 211 may be formed to extend from a lower end portion of the groove 210a to a bottom surface of the first pad portion 210 in a downward direction (in -Z direction). In addition, the non-conductive portion 212 may be formed to extend from an upper end of the conductive portion 211 to an upper surface of the polishing pad 200 in an upward direction (in +Z direction). A groove 210a may be formed in the non-conductive portion 212.

The conductive portion 211 may partially include regions having different concentrations of conductive particles. More specifically, the conductive portion 211 may include a first conductive region 211a and a second conductive region 211b. The first conductive region 211a may include a first concentration of glassy carbon. The second conductive region 211b may include a second concentration of glassy carbon. In this case, the first concentration of glassy carbon may be different from the second concentration of glassy carbon. For example, the first concentration of glassy carbon may be greater than the second concentration of glassy carbon, or the first concentration of glassy carbon may be less than the second concentration of glassy carbon. As described above, in the case of the first pad portion 210 of Example 4, the conductive portion 211 may have conductive particles disposed unevenly.

The first conductive region 211a may be disposed in a ‘central portion B10 and an edge portion B20’ of the first pad portion 210, respectively. The second conductive region 211b may be disposed in an ‘intermediate region B30’ of the first pad portion 210 located between the central portion B10 and the edge portion B20 described above. Accordingly, as shown in FIG. 7A, based on a cross-sectional view viewed in a side direction (e.g., in Z-X plane direction) of the polishing pad 200, the first conductive region 211a and the second conductive region 211b may be disposed alternately in the width direction (X) or radial direction of the polishing pad 200. In addition, as shown in FIG. 7B, when viewed from above the polishing pad 200, the second conductive region 211b may be disposed to be surrounded by the first conductive regions 211a between the central portion B10 and the edge portion B20.

In addition, a second pad portion 220 may be formed of a conductive material. For example, a concentration of the glassy carbon included in the second pad portion 220 may be greater than the first concentration and the second concentration, or may be less than the first concentration and the second concentration. As another example, the concentration of the glassy carbon included in the second pad portion 220 may be a concentration between the first concentration and the second concentration.

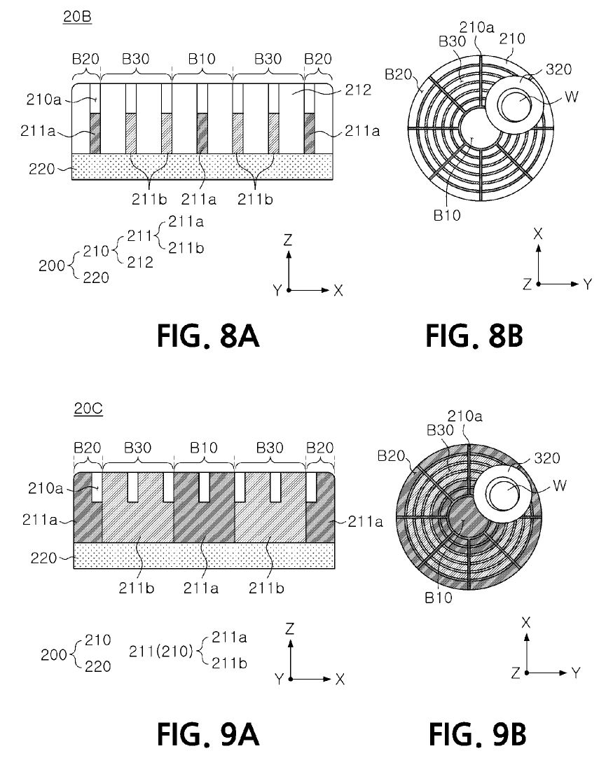

FIG. 8A is a cross-sectional view illustrating a polishing pad of an electrochemical mechanical polishing apparatus according to another embodiment of the present inventive concept viewed from the direction, taken along line I-I’ of FIGS. 1 and 8B is a plan view illustrating a polishing pad thereof viewed from above.

Referring to FIGS. 8A and 8B, in the case of an electrochemical mechanical polishing apparatus 20B according to another embodiment of the present inventive concept (hereinafter, Embodiment 5), a first pad portion 210 of the polishing pad 200 may include a conductive portion 211 and a non-conductive portion 212. In addition, the second pad portion 220 may be formed of a conductive material. In this case, most of the features of the electrochemical mechanical polishing apparatus 20B are the same or similar to the Example 1 described above, so redundant descriptions thereof will be omitted and descriptions thereof will be provided, focusing on differences thereof.

The conductive portion 211 according to Example 5 may be disposed below a groove 210a. The conductive portion 211 may be formed to extend from directly below the groove 210a to a bottom surface of the first pad portion 210 in a downward direction (in -Z direction). Accordingly, the conductive portion 211 may be disposed to overlap the groove 210a when viewed from above the polishing pad 200.

The conductive portion 211 may include a first conductive region 211a including a first concentration of glassy carbon, and a second conductive region 211b including a second concentration of glassy carbon. The first conductive region 211a may be disposed in a central portion B10 and an edge portion B20 of the first pad portion 210, and the second conductive region 211b may be disposed in an intermediate region B30 of the first pad portion 210. In this case, the number of first conductive regions 211a included in the central portion B10 and/or the edge portion B20 and the number of second conductive regions 211b included in the intermediate region B30 may be increased or decreased as needed. In addition, as described above, the first concentration of glassy carbon may be the same as the second concentration of glassy carbon or the concentrations may be different from each other.

In the above case, the non-conductive portion 212 may be formed in a region of the first pad portion 210 in which a groove 210a is not disposed. Accordingly, as shown in FIG. 8A, based on a cross-sectional view viewed in a side direction (e.g., in Z-X plane direction) of the polishing pad 200, the first conductive region 211a, the second conductive region 211b, and the non-conductive portion 212 may be disposed alternately in the width direction (X) of the polishing pad 200. In addition, since the non-conductive portion 212 is formed to overlap with the groove 210a as described above, when the polishing pad 200 is viewed from above, only the groove 210a and the non-conductive portion 212 may be disposed on the upper surface of the polishing pad 200 as shown in FIG. 8B.

FIG. 9A is a cross-sectional view illustrating a polishing pad of an electrochemical mechanical polishing apparatus according to another embodiment of the present inventive concept viewed from the direction, taken along line I-I’ of FIGS. 1 and 9B is a plan view illustrating a polishing pad thereof viewed from above.

Referring to FIGS. 9A and 9B, in the case of an electrochemical mechanical polishing apparatus 20C according to another embodiment of the present inventive concept (hereinafter, Example 6), only a conductive portion 211 may be provided on a first pad portion 210 of a polishing pad 200. In this case, most of the features of the electrochemical mechanical polishing apparatus 20C are the same or similar to those of Example 1 described above, so redundant descriptions thereof will be omitted and descriptions thereof will be provided, focusing on differences thereof.

In the case of Example 6, since a first pad portion 210 does not include a non-conductive portion 212, the first pad portion 210 may be formed entirely of a conductive material. In this case, the first pad portion 210 may be in a form in which glassy carbon particles, which are conductive particles, are disposed unevenly. That is, the first pad portion 210 may include a first conductive region 211a and a second conductive region 211b. The first conductive region 211a is a region including a first concentration of glassy carbon, and the second conductive region 211b is a region including a second concentration of glassy carbon, and the first concentration and the second concentration are different from each other, which is the same as described above.

In this case, the first conductive region 211a may be disposed in a central portion B10 and an edge portion B20 of the first pad portion 210. The second conductive region 211b may be disposed in an intermediate region B30 of the first pad portion 210. Accordingly, as shown in FIG. 9A, based on a cross-sectional view viewed in a side direction (e.g., in ZX plane direction) of the polishing pad 200, the first conductive region 211a and the second conductive region 211b may be alternately disposed in the width direction (X) or the radial direction. In addition, as shown in FIG. 9B, when viewed from above the polishing pad 200, the second conductive region 211b may be disposed to be surrounded by the first conductive regions 211a between the central portion B10 and the edge portion B20.

In addition, a second pad portion 220 may be formed of a conductive material. For example, a concentration of glassy carbon included in the second pad portion 220 may be greater than the first concentration and the second concentration, or may be less than the first concentration and the second concentration. As another example, the concentration of glassy carbon included in the second pad portion 220 may be a concentration between the first concentration and the second concentration.

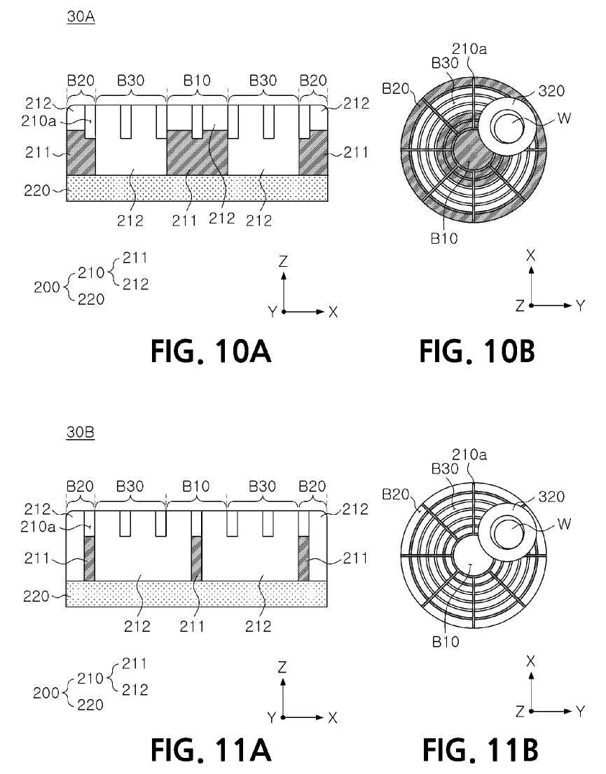

FIG. 10A is a cross-sectional view illustrating a polishing pad of an electrochemical mechanical polishing apparatus according to another embodiment of the present inventive concept viewed from the direction, taken along line I-I’ of FIGS. 1 and 10B is a plan view illustrating a polishing pad thereof viewed from above.

Referring to FIGS. 10A and 10B, in the case of an electrochemical mechanical polishing apparatus 30A according to another embodiment of the present inventive concept (hereinafter, Example 7), a first pad portion 210 of a polishing pad 200 may include a conductive portion 211 and a non-conductive portion 212. In this case, most of the features of the electrochemical mechanical polishing apparatus 30A are the same or similar to those of Example 1 described above, so redundant descriptions thereof will be omitted and descriptions thereof will be provided, focusing on differences thereof.

In the case of Example 7, a conductive portion 211 may be disposed below a groove 210a. In addition, the conductive portion 211 may be disposed in a central portion B10 and an edge portion B20 of the first pad portion 210. That is, the conductive portion may extend from directly below the groove 210a to a bottom surface of the first pad portion 210 in a downward direction (in -Z direction), in the central portion B10 and the edge portion B20.

The non-conductive portion 212 may be disposed in an intermediate region B30 of the first pad portion 210. In addition, the non-conductive portion 212 may be disposed on the conductive portion 211, in the central portion B10 and the edge portion B20. That is, the non-conductive portion 212 may be formed to extend from directly above the conductive portion 211 of the central portion B10 and the edge portion B20 in an upward direction (in +Z direction) to an upper surface of the first pad portion 210 (an upper surface of the polishing pad 200). Accordingly, the groove 210a of Example 7 may be disposed in the non-conductive portion 212.

In the above case, as shown in FIG. 10A, based on a cross-sectional view viewed in a side direction (e.g., Z-X plane direction) of the polishing pad 200, the first conductive region 211a and the second conductive region 211b may be disposed alternately in the width direction (X) and the radial direction of the polishing pad 200, below the groove 210a. In addition, as shown in FIG. 10B, when viewed from above the polishing pad 200, the non-conductive portion 212 may be disposed to be surrounded by the conductive portions 211, between the central portion B10 and the edge portion B20.

In addition, a second pad portion 220 may be formed of a conductive material. For example, a concentration of glassy carbon included in the second pad portion 220 may be the same as the concentration and the concentration of glassy carbon included in the conductive portion 211, or may be less than the concentration of glassy carbon included in the conductive portion 211. As another example, the concentration of glassy carbon included in the second pad portion 220 may be greater than the concentration of glassy carbon included in the conductive portion 211.

FIG. 11A is a cross-sectional view illustrating a polishing pad of an electrochemical mechanical polishing apparatus according to another embodiment of the present inventive concept viewed from the direction, taken along line I-I’ of FIGS. 1 and 11B is a plan view illustrating a polishing pad thereof viewed from above.

Referring to FIGS. 11A and 11B, in the case of an electrochemical mechanical polishing apparatus 30B according to another embodiment of the present inventive concept (hereinafter, Example 8), a first pad portion 210 of a polishing pad 200 may include a conductive portion 211 and a non-conductive portion 212. In this case, most of the features of the electrochemical mechanical polishing apparatus 30B are the same or similar to those of Example 1 described above, so redundant descriptions thereof will be omitted and descriptions thereof will be provided, focusing on differences thereof.

In the case of Example 8, the conductive portion 211 may be disposed below a groove 210a. In addition, the conductive portion 211 may be disposed only in a portion of a central portion B10 and an edge portion B20 of the first pad portion 210. That is, the conductive portion 211 may be disposed only below a portion of the grooves 210a, in the central portion B10 and the edge portion B20.

The non-conductive portion 212 may be disposed in an intermediate portion B30 of the first pad portion 210. In addition, the non-conductive portion 212 may be disposed on the conductive portion 211, in the central portion B10 and the edge portion B20. Accordingly, the conductive portion 211 may be surrounded by the non-conductive portion 212 and the groove 210a, based on a cross-sectional view viewed in a side direction (e.g., in ZX plane direction) of the polishing pad 200 as shown in FIG. 11A. In addition, as shown in FIG. 11B, when viewed from above the polishing pad 200, only the non-conductive portion 212 and the groove 210a may be disposed on an upper surface of the first pad portion 210.

In addition, a second pad portion 220 may be formed of a conductive material. For example, a concentration of glassy carbon included in the second pad portion 220 may be the same as the concentration and the concentration of glassy carbon included in the conductive portion 211, or may be less than the concentration of glassy carbon included in the conductive portion 211. As another example, the concentration of glassy carbon included in the second pad portion 220 may be greater than the concentration of glassy carbon included in the conductive portion 211.

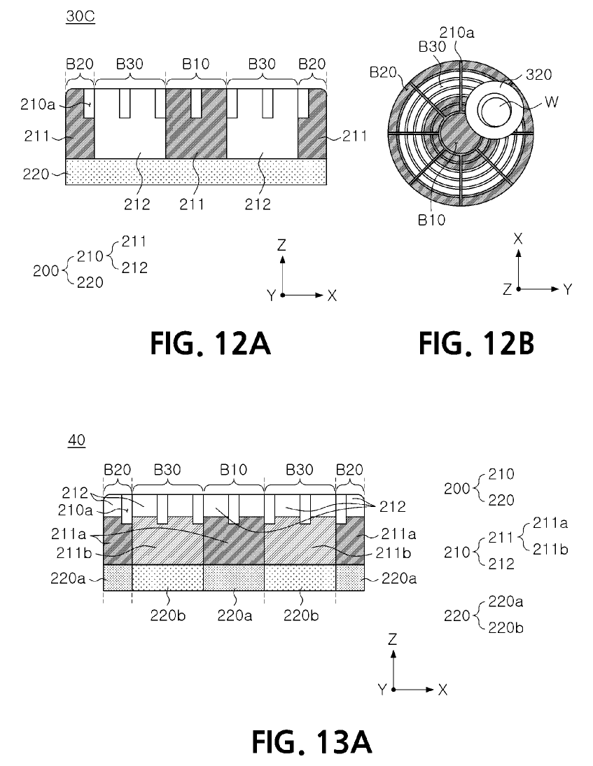

FIG. 12A is a cross-sectional view illustrating a polishing pad of an electrochemical mechanical polishing apparatus according to another embodiment of the present inventive concept viewed from the direction, taken along line I-I’ of FIGS. 1 and 12B is a plan view illustrating a polishing pad thereof viewed from above.

Referring to FIGS. 12A and 12B, in the case of an electrochemical mechanical polishing apparatus 30C according to another embodiment of the present inventive concept (hereinafter, Example 9), a first pad portion 210 of a polishing pad 200 may include a conductive portion 211 and a non-conductive portion 212. In this case, most of the features of the electrochemical mechanical polishing apparatus 30C are the same or similar to those of Example 1 described above, so redundant descriptions thereof will be omitted and descriptions thereof will be provided, focusing on differences thereof.

In the case of Example 9, the conductive portion 211 may be disposed in a central portion B10 and an edge portion B20 of a first pad portion 210. The non-conductive portion 212 may be disposed in an intermediate portion B30 of the first pad portion 210. Accordingly, as shown in FIG. 12A, based on a cross-sectional view viewed in a side direction (e.g., ZX plane direction) of the polishing pad 200, the conductive portion 211 and the non-conductive portion 212 may be alternately disposed in the width direction (X) or the radial direction. In addition, as shown in FIG. 12B, when viewed from above the polishing pad 200, the non-conductive portion 212 may be disposed in a form surrounded by conductive portions 211 between the central portion B10 and the edge portion B20. A conductive portion 211, a non-conductive portion 212, and a groove 210a may all be disposed on an upper surface of the polishing pad 200 of Example 9.

In addition, a second pad portion 220 may be formed of a conductive material. For example, a concentration of glassy carbon included in the second pad portion 220 may be the same as the concentration and the concentration of glassy carbon included in the conductive portion 211, or may be less than the concentration of glassy carbon included in the conductive portion 211. As another example, the concentration of glassy carbon included in the second pad portion 220 may be greater than the concentration of glassy carbon included in the conductive portion 211.

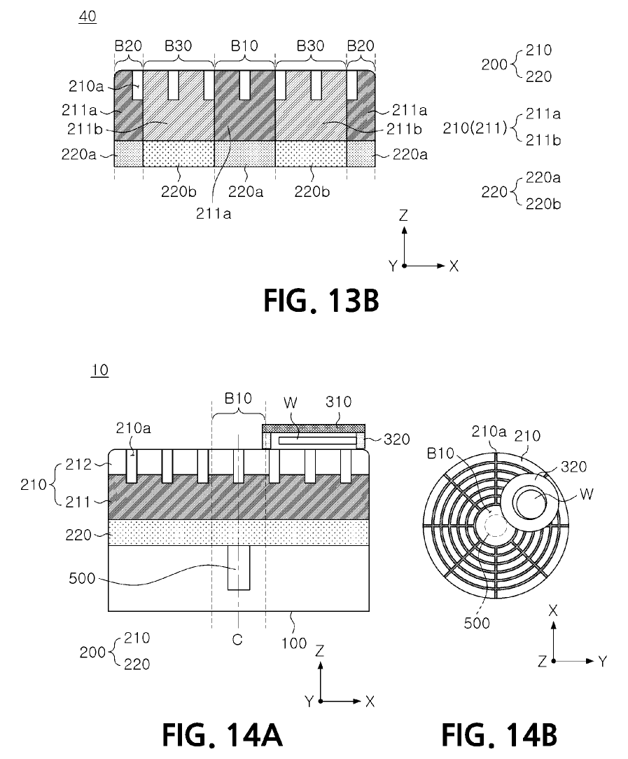

FIGS. 13A and 13B are cross-sectional views illustrating a polishing pad of an electrochemical mechanical polishing apparatus according to other embodiments of the present inventive concept viewed from the direction, taken along line I-I’ of FIG. 1.

Referring to FIGS. 13A and 13B, in the case of an electrochemical mechanical polishing apparatus 40 according to another embodiment of the present inventive concept (hereinafter, Example 10), a second pad portion 220 may be formed of a conductive material. In this case, most of the features of the electrochemical mechanical polishing apparatus 30C are the same or similar to those of Example 1 described above, so redundant descriptions thereof will be omitted and descriptions thereof will be provided, focusing on differences thereof.

In the case of Example 10, glassy carbon particles, which are conductive particles, may be disposed unevenly in the second pad portion 220. For example, the second pad portion 220 may include a ‘third conductive region 220a’ including a third concentration of glassy carbon and a ‘fourth conductive region 220b’ including a fourth concentration of glassy carbon. The third concentration may be greater than or less than the fourth concentration. In this case, the third conductive region 220a may be disposed in a central portion B10 and an edge portion B20 of the second pad portion 220, and the fourth conductive region 220b may be disposed in an intermediate region B30 of the second pad portion 220.

The first pad portion 210 may have a first conductive region 211a and a second conductive region 211b alternately disposed in the width direction (X) or radial direction described above. For example, as shown in FIG. 13A, the first pad portion 210 may have the same shape as the polishing pad 200 of Example 4 described above. As another example, as shown in FIG. 13B, the first pad portion 210 may have the same shape as the above-described Example 6. In this case, a first conductive region 211a may be disposed to face the third conductive region 220a in a line in a height direction, in the central portion B10 and the edge portion B20. A second conductive region 211b may be disposed in a line facing the fourth conductive region 220b in the height direction (Z) in the intermediate region B30.

In the above case, a third concentration and a fourth concentration are different concentrations, and at the same time, the third concentration and the fourth concentration can be different concentrations from at least one of the first concentration and the second concentration. Thereby, a plurality of conductive regions (i.e., the central region B10, the edge portion region B20, and the intermediate region B30 of the first pad portion 210 and the second pad portion 220) having various concentrations may be formed on the polishing pad 200.

Meanwhile, in the above-described Examples, a separation distance between the central portion B10 and the edge portion B30 may be a length smaller than a diameter of a wafer W. The distance may mean, for example, a straight-line distance between the central portion B10 and the edge portion B30 measured in a radial direction of the polishing pad 200.

In general, during an ECMP process, the ECMP may be performed on the wafer W in a state in which the polishing head 300 is located between the central portion B10 and the edge portion B30 of the polishing pad 200. In this case, the central portion B10 and the edge portion B30 may be spaced apart by a distance similar to or smaller than the diameter of the wafer W, so that the edge portion of the wafer W may be in contact with the central portion B10 and the edge portion B30 of the polishing pad 200, and the ECMP process can be performed. As described above, the central portion B10 and the edge portion B30 are regions in which the first conductive region 211 is disposed, so that the flow of slurry S in the edge portion of the wafer W may be more effectively controlled by applying current and voltage.

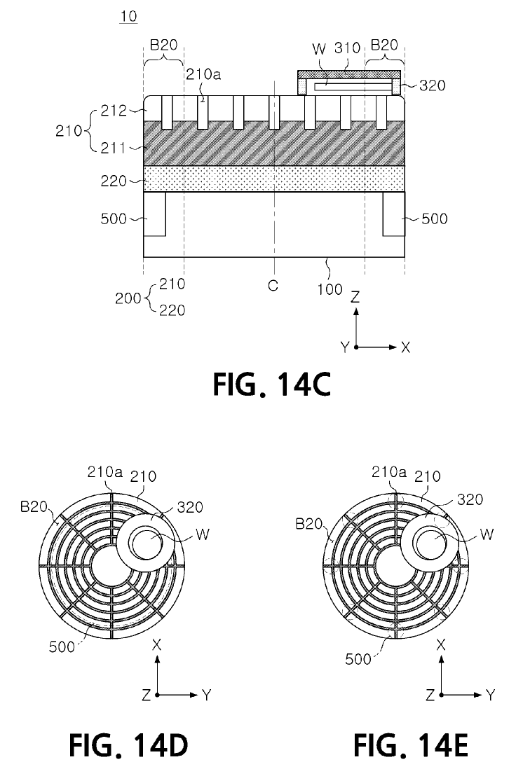

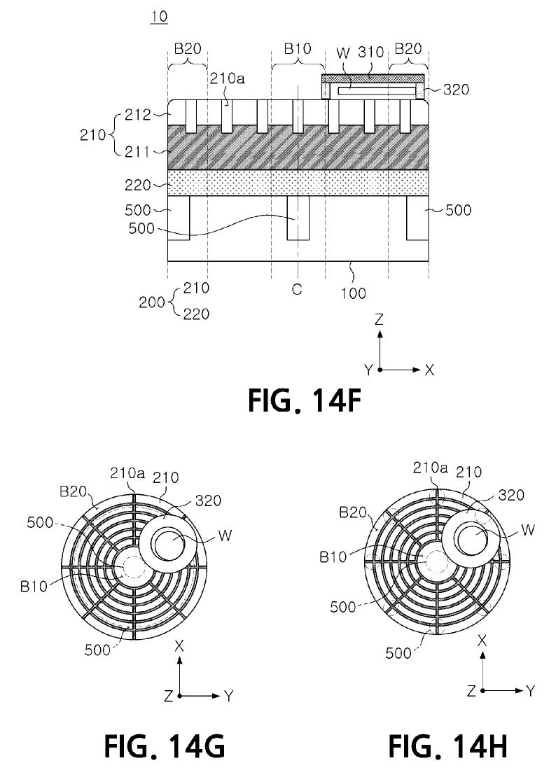

FIG. 14A is a cross-sectional view illustrating an electrochemical mechanical polishing apparatus including an electrode according to example embodiments of the present inventive concept viewed from the direction, taken along line I-I’ of FIGS. 1 and 14B is a plan view illustrating a polishing pad thereof viewed from above. FIG. 14C is a cross-sectional view illustrating an electrochemical mechanical polishing apparatus including an electrode according to other embodiments of the present inventive concept viewed from the direction, taken along line I-I’ of FIG. 1, and FIGS. 14D and 14E are plan views illustrating a polishing pad thereof viewed from above. FIG. 14F is a cross-sectional view illustrating an electrochemical mechanical polishing apparatus including an electrode according to other embodiments of the present inventive concept viewed from the direction, taken along line I-I’ of FIG. 1, and FIGS. 14G and 14H are plan views illustrating a polishing pad thereof viewed from above.

Referring to FIGS. 14A to 14H, as in Examples 1 to 10 described above, when the second pad portion 220 includes a conductive material, the electrode 500 may be connected to the second pad portion 220. In this case, the polishing pad 200 may be the same as the polishing pad 200 included in any one of Examples 1 to 10 described above. Hereinafter, for convenience of explanation, the description will be provided, focusing on the polishing pad 200 of Example 1, but an example embodiment thereof is not limited thereto.

The electrode 500 may be connected to at least one of a central portion B10 and an edge portion B20, of lower surfaces of the second pad portion 220. To this end, at least one electrode 500 may be provided. In an example embodiment, referring to FIGS. 14A and 14B, the electrode 500 may be connected to the central portion B10 of the second pad portion 220. In this case, one electrode 500 may be provided. One electrode 500 may be coupled to a center of the lower surface of the second pad portion 220 to be placed the same line as the center C of the polishing pad 200.

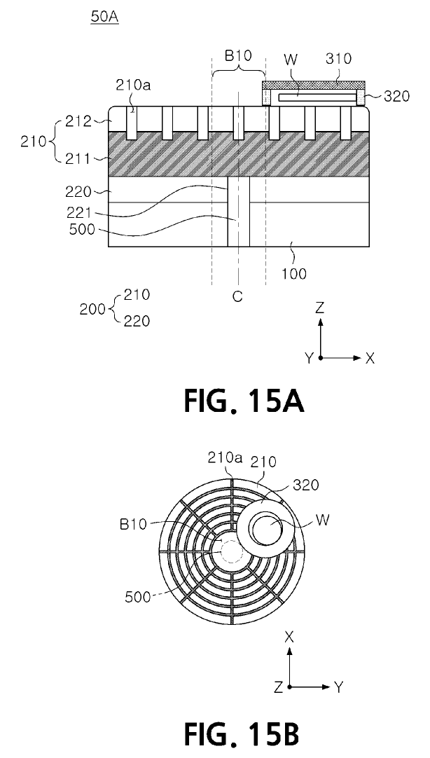

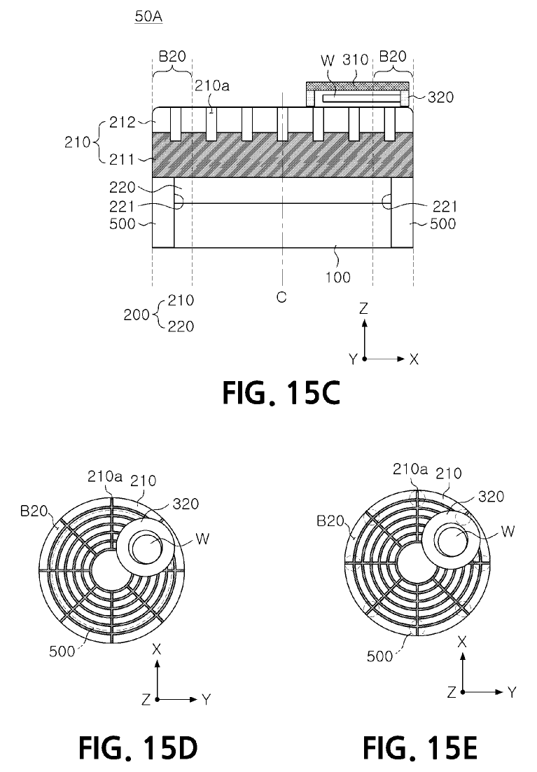

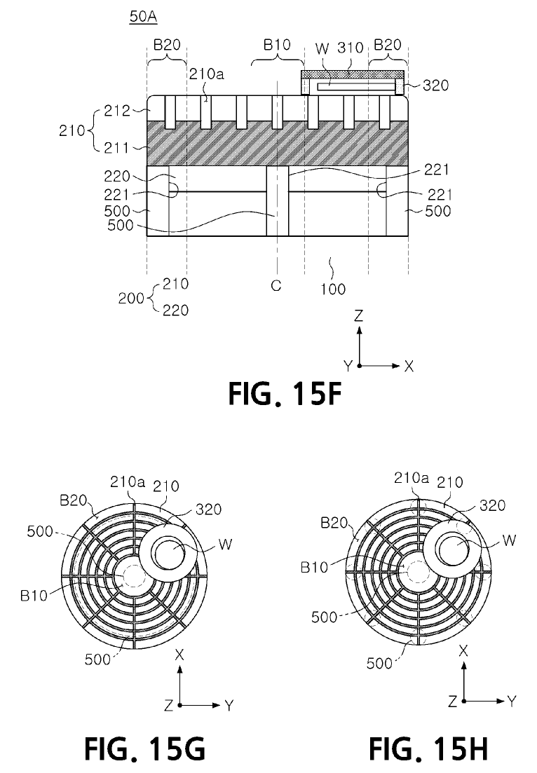

In another embodiment, referring to FIGS. 14C- 14E, the electrode 500 may be connected to the edge portion B20. For example, as in FIGS. 14C and 14D, the electrode 500 may be provided as a single electrode having a ring shape, and may be connected to the edge portion of the lower surface of the second pad portion 220. As another example, as in FIGS. 15C and 15E, a plurality of electrodes 500 may be provided. The plurality of electrodes 500 may be coupled to the edge portion of the lower surface of the second pad portion 220 in a state in which the plurality of electrodes 500 are disposed to be spaced apart in a circumferential direction of the second pad portion 220.

In another embodiment, referring to FIGS. 14F - 14H, the electrodes 500 may be connected to the central portion B10 and the edge portion B20, respectively. In this case, at least two electrodes 500 may be provided. For example, as in FIGS. 14F and 14D, the electrode 500 may have a ring-shaped single electrode (first electrode) and a pillar-shaped electrode (second electrode). The first electrode 500 may be connected to the edge portion of the lower surface of the second pad portion 220, and the second electrode 500 may be coupled to the center of the lower surface of the second pad portion 220.

As another example, as in FIGS. 14F and 14E, a plurality of pillar-shaped electrodes 500 may be provided. One of the plurality of electrodes 500 may be coupled to the center of the lower surface of the second pad portion 220. The remaining electrodes 500 may be coupled to the edge portion of the lower surface of the second pad portion 220 in a state in which the plurality of electrodes 500 are disposed to be spaced apart in the circumferential direction of the second pad portion 220.

FIG. 15A is a cross-sectional view illustrating an electrochemical mechanical polishing apparatus including an electrode according to other embodiments of the present inventive concept viewed from the direction, taken along line I-I’ of FIG. 1, and FIG. 15B is a plan view illustrating a polishing pad thereof viewed from above. FIG. 15C is a cross-sectional view illustrating an electrochemical mechanical polishing apparatus including an electrode according to other embodiments of the present inventive concept viewed from the direction, taken along line I-I’ of FIG. 1, and FIGS. 15D and 15E are plan views illustrating a polishing pad thereof viewed from above. FIG. 15F is a cross-sectional view illustrating an electrochemical mechanical polishing apparatus including an electrode according to other embodiments of the present inventive concept viewed from the direction, taken along line I-I’ of FIG. 1, and FIGS. 15G and 15H are plan views illustrating a polishing pad thereof viewed from above.

Referring to FIGS. 15A-15H, an electrochemical mechanical polishing apparatus 50A according to another embodiment of the present inventive concept (hereinafter, Example 11) may include a first pad portion 210 including a conductive material and a second pad portion 220. In this case, most of the features of the electrochemical mechanical polishing apparatus 50 are the same or similar to those of Example 1 described above, so redundant descriptions thereof will be omitted and descriptions thereof may be provided, focusing on differences thereof.

In the case of Example 11, the second pad portion 220 may be formed of a non-conductive material. The second pad portion 220 may be formed of, for example, polyurethane, but an example embodiment thereof is not limited thereto. In this case, the second pad portion 220 may be provided with a through portion 221. The through portion 221 may extend from a bottom surface of the second pad portion 220 to an upper surface of the second pad portion 220 in a vertical direction (Z), and may have a form penetrating the second pad portion 220.

An electrode 500 may be connected to the first pad portion 210, unlike Examples 1 to 10 described above. The electrode 500 of Example 11 may be disposed below the polishing pad 200, and may extend upwardly (in +Z direction) from the platen 100. In this case, the electrode 500 may extend in a state in which a lower end portion of the electrode 500 is coupled to the platen 100 and an upper end portion thereof is partially inserted into the through portion 221 to be coupled to a bottom surface of the first pad portion210. In this manner, the electrode 500 may be directly coupled to the first pad portion 210.

The electrode 500 may be connected to at least one of a central portion B10 and an edge portion B20 of the lower surface of the first pad portion 210. To this end, at least one electrode 500 may be provided. Accordingly, the second pad portion 220 may be provided with at least one through portion 221. In this case, the through portion 221 may be disposed in positions corresponding to each other so that the electrode 500 may be inserted one-to one therethrough.

In an example embodiment, referring to FIGS. 15A and 15B, the electrode 500 may be connected to the central portion B10 of the first pad portion 210. In this case, the electrode 500 and the through portion 221 may be provided one by one. The electrode 500 may be disposed on the same line as the center C of the polishing pad 200 by penetrating through the through portion 221 and being coupled to the center of the lower surface of the second pad portion 220.

In another embodiment, referring to FIGS. 15C-15E, the electrode 500 may be connected to the edge portion B20. For example, as in FIG. 15C and 15D, when the electrode 500 has a form of a single electrode having a ring shape, the through portion 221 may be provided in a form of a through-hole having a ring shape to correspond thereto. The electrode 500 may be coupled to the edge portion of the lower surface of the first pad portion 210 by passing through the through portion 221.

As another example, as in FIGS. 15F and 15H, the electrode 500 and the through portion 221 may be provided in plural. The electrodes 500 and the through portions 221 may be disposed to be spaced apart in a circumferential direction of the second pad portion 220. The electrodes 500 may be inserted into the through portion 221 one-to-one therethrough, and may be respectively coupled to the edge portion of the lower surface of the first pad portion 210.

In another embodiment, referring to FIGS. 15F-15H, the electrode 500 may be respectively connected to a central portion B10 and an edge portion B20. In this case, two or more electrodes 500 and through portions 221 may be provided, respectively. For example, as in FIGS. 15F and 15G, the electrode 500 may be provided with a single electrode having a ring shape (first electrode) and a through portion (first through portion), and an electrode having a pillar shape (second electrode) and a through portion (second through portion). The first electrode 500 may pass through the first through portion 221 and be coupled to the edge portion of the lower surface of the second pad portion 220. The second electrode 500 may pass through the first through portion 221 and be coupled to the central portion of the lower surface of the second pad portion 220.

As another example, as in FIGS. 15F and 15H, a plurality of pillar-shaped electrodes 500 and through portions 221 may be provided. One of the plurality of electrodes 500 may pass through the through portion 221 and be coupled to the center of the lower surface of the second pad portion 220. The remaining electrodes 500 and the through portions 221 may be disposed to be spaced apart from each other in a circumferential direction of the second pad portion 220. The electrodes 500 may be inserted into the through portion 221 one-to-one therethrough and respectively be coupled to the edge portion of the lower surface of the first pad portion 210.

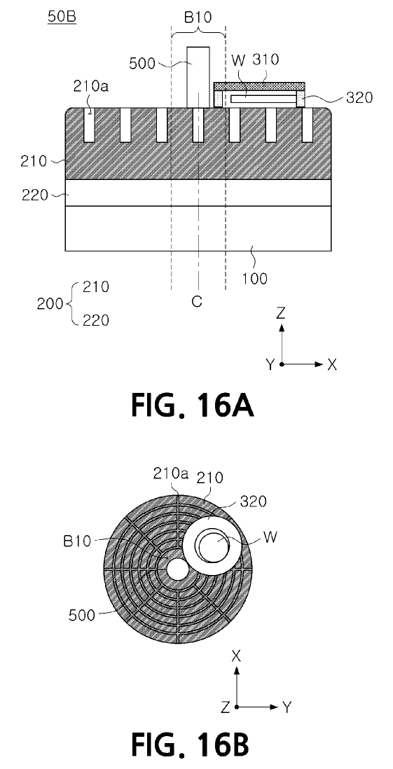

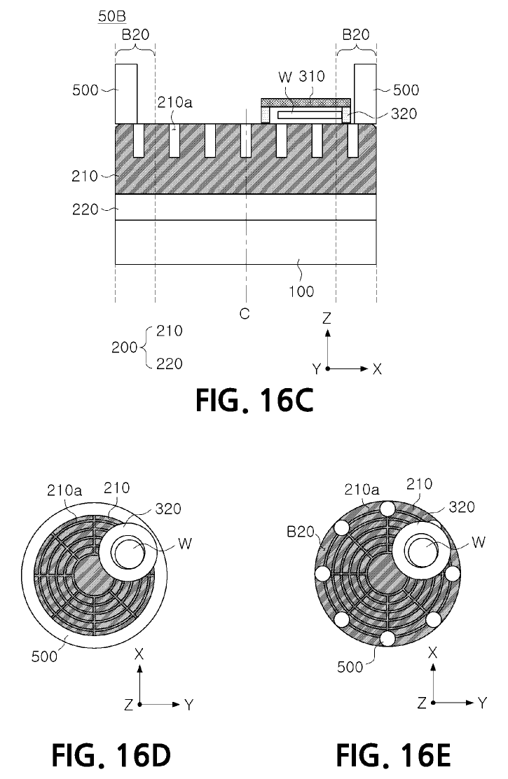

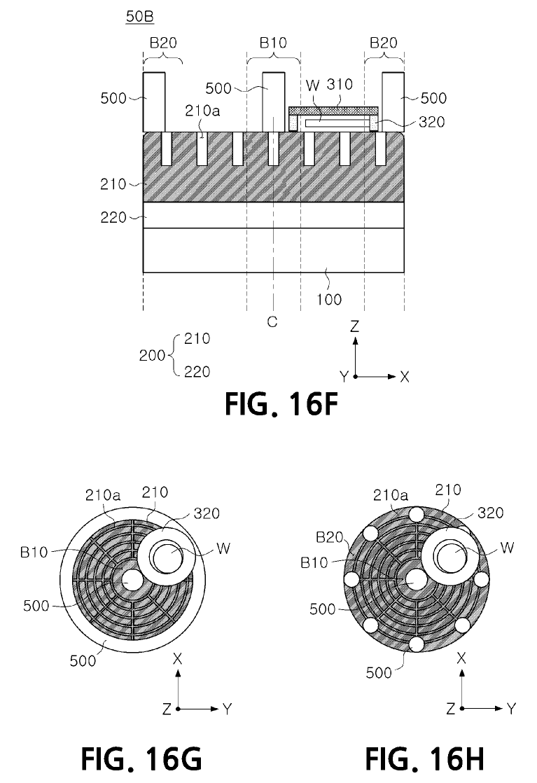

FIG. 16A is a cross-sectional view illustrating an electrochemical mechanical polishing apparatus including an electrode according to other embodiments of the present inventive concept viewed from the direction, taken along line I-I’ of FIG. 1, and FIG. 16B is a plan view illustrating a polishing pad thereof viewed from above. FIG. 16C is a cross-sectional view illustrating an electrochemical mechanical polishing apparatus including an electrode according to other embodiments of the present inventive concept viewed from the direction, taken along line I-I’ of FIG. 1, and FIGS. 16D and 16E are plan views illustrating a polishing pad thereof viewed from above. FIG. 16F is a cross-sectional view illustrating an electrochemical mechanical polishing apparatus including an electrode according to other embodiments of the present inventive concept viewed from the direction, taken along line I-I’ of FIG. 1, and FIGS. 16G and 16H are plan views illustrating a polishing pad thereof viewed from above.

Referring to FIGS. 16A to 16H, in the case of an electrochemical mechanical polishing apparatus 50B according to another embodiment of the present inventive concept (hereinafter, Example 12), the electrochemical mechanical polishing apparatus 50B may include a first pad portion 210 and a second pad portion 220. In this case, most of the features of the electrochemical mechanical polishing apparatus 50B are the same or similar to those of Example 1 described above, so redundant descriptions thereof will be omitted and descriptions thereof will be provided, focusing on the differences.

In the case of Example 11, the second pad portion 220 may be formed of a non-conductive material. The second pad portion 220 may be formed of, for example, polyurethane. In this case, the first pad portion 210 may be formed of a conductive material. In this case, the first pad portion 210 may be formed entirely of a conductive material, including an upper surface of the polishing pad 200, as in the Example 3 or Example 6 described above.

The electrode 500 may be connected to a first pad portion 210. The electrode 500 of Example 11 may be disposed above the polishing pad 200. A lower end portion of the electrode 500 may be directly connected to an upper surface of the first pad portion 210.

The electrode 500 may be connected to at least one of a central portion B10 and an edge portion B20 of the upper surface of the first pad portion 210. To this end, at least one electrode 500 may be provided. In an example embodiment, referring to FIGS. 16A and 16B, the electrode 500 may be connected to the central portion B10 of the first pad portion 210. The electrode 500 may be provided in one and may be coupled to a center of the upper surface of the first pad portion 210. Accordingly, the electrode 500 may be placed on the same line as the center C of the polishing pad 200. In this case, the polishing pad 300 may rotate and swing between the electrode 500 and the edge portion B20, and an ECMP process may be performed, so that a collision between the polishing head 300 and the electrode 500 does not occur.

In another embodiment, referring to FIGS. 16C-16E, the electrode 500 may be connected to the edge portion B20. For example, as in FIGS. 16C and 16D, the electrode 500 may be provided as a single electrode having a ring shape, and may be coupled to the edge portion of the upper surface of the first pad portion 210. As another example, as in FIGS. 16C and 16E, the electrode 500 may be provided in plural. The plurality of electrodes 500 may be coupled to an edge portion of a lower surface of the second pad portion 220, while being disposed to be spaced apart in a circumferential direction of the second pad portion 220. In such a case, to prevent a collision between the polishing head 300 and the electrode 500, the polishing head 300 may rotate and swing inside the ring-shaped electrode 500 or between the electrodes 500 so that the ECMP process may be performed.

In another embodiment, referring to FIGS. 16F-16H, the electrodes 500 may be respectively connected to a central portion B10 and an edge portion B20. To this end, at least two electrodes 500 may be provided. For example, as in FIGS. 16F and 16G, the electrode 500 may have a ring-shaped single electrode (first electrode) and a pillar-shaped electrode (second electrode). The first electrode 500 may be connected to an edge portion of the upper surface of the first pad portion 210, and the second electrode 500 may be coupled to the center of the upper surface of the first pad portion 210.

As another example, as in FIGS. 16F and 16H, a plurality of pillar-shaped electrodes 500 may be provided. One of the plurality of electrodes 500 may be coupled to the center of the upper surface of the first pad portion 210. The remaining electrodes 500 may be coupled to the edge portion of the upper surface of the first pad portion 210, while being disposed to be spaced apart from each other in a circumferential direction of the first pad portion 220.

As described above, the polishing head 300 may rotate and swing between the electrodes 500 and the ECMP process may be performed, so that a collision between the polishing head 300 and the electrodes 500 does not occur.

As described above, since the electrode 500 is provided so that the electrode 500 may be disposed at various positions above or below the polishing pad 200, the design may be easily changed according to the specifications or structure of the polishing pad 200 and the electrochemical mechanical polishing apparatus 10, thereby improving space utilization.

The electrochemical mechanical polishing apparatus (10, 10A, 10B, 10C, 20A, 20B, 20C, 30A, 30B, 30C, 40, 50A, 50B) according to the example embodiments of the present inventive concept as described above is configured such that the retainer ring 320 includes a conductive material, so that when current and voltage are applied through the electrode 500, an electric field can be generated in the retainer ring 320. In addition, by controlling the electric field generated in the retainer ring 320 through the adjustment of the applied current and voltage, the flow of the slurry S supplied to the upper surface of the polishing pad 200 may be more effectively controlled during the process of flowing into or discharging from the retainer ring 320.

In addition, since the first pad portion 210 of the polishing pad (200) is configured to include a conductive material, an electric field may be generated in the polishing pad 200, when current and voltage are applied through the electrode 500. Furthermore, by controlling the electric field generated in the retainer ring 320 through the adjustment of the applied current and voltage, the slurry S may be adjusted to be sufficiently and evenly supplied to the edge portion of the wafer W, a rebound phenomenon at the edge portion of the wafer W may be reduced during the ECMP process, and an edge portion removal rate of the wafer W may be effectively controlled.

As set forth above, according to the example embodiments described above, an electrochemical mechanical polishing apparatus is configured such that a retainer ring includes a conductive material, so that when current and voltage are applied through an electrode, an electric field may be generated in the retainer ring, and by controlling the electric field generated through adjustment of the applied current and voltage, a flow of slurry may be effectively controlled when slurry is introduced or discharged between a polishing pad and the retainer ring.

In addition, the electrochemical mechanical polishing apparatus according to example embodiments of the present inventive concept is configured such that a first pad portion of the polishing pad includes a conductive material, so that when current and voltage are applied through the electrode, an electric field may be generated in the polishing pad. In addition, by controlling the electric field generated by adjusting the applied current and voltage, and by controlling the slurry to be supplied sufficiently and evenly to an edge portion of a wafer, a rebound phenomenon at the edge portion of the wafer during the ECMP process may be reduced, and the edge removal rate of the wafer may be effectively controlled.

The various advantageous and beneficial advantages and effects of the present inventive concept are not limited to the above-described contents, and will be more easily understood in the course of explaining specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. An electrochemical mechanical polishing apparatus, comprising:
a platen;
a polishing pad disposed above the platen, and including a first pad portion having a groove formed concavely inwardly on an upper surface of the first pad portion, a conductive portion formed of a conductive material, and a non-conductive portion formed of a non-conductive material, and a second pad portion disposed below the first pad portion and including a conductive material;
a polishing head including a retainer ring supporting a wafer and including a conductive material, and disposed above the polishing pad to press the wafer; and
an electrode disposed below the polishing pad, and connected to the second pad portion.

2. The electrochemical mechanical polishing apparatus of claim 1, wherein the conductive portion is disposed below the groove at least partially, and
the non-conductive portion is disposed on the conductive portion.

3. The electrochemical mechanical polishing apparatus of claim 2, wherein the conductive portion includes a first conductive region including a first concentration of glassy carbon, and a second conductive region including a second concentration of glassy carbon.

4. The electrochemical mechanical polishing apparatus of claim 3, wherein the first conductive region and the second conductive region are disposed alternately in a radial direction of the polishing pad.

5. The electrochemical mechanical polishing apparatus of claim 1, wherein the conductive portion and the non-conductive portion are disposed alternately in the radial direction of the polishing pad.

6. The electrochemical mechanical polishing apparatus of claim 5, wherein the conductive portion is disposed in a central portion and an edge portion of the first pad portion, respectively, and
the non-conductive portion is disposed in an intermediate region between the central portion and the edge portion of the first pad portion in the radial direction of the polishing pad.

7. The electrochemical mechanical polishing apparatus of claim 1, wherein the retainer ring is formed of a composite material including a non-conductive material and a conductive material.

8. The electrochemical mechanical polishing apparatus of claim 1, wherein the retainer ring includes an upper end portion and a lower end portion, separated from each other,
the upper end portion includes a conductive material, and
the lower end portion includes a non-conductive material and is disposed to face an upper surface of the polishing pad.

9. The electrochemical mechanical polishing apparatus of claim 1, wherein the electrode is disposed in a central portion of the second pad portion and is connected to a lower surface of the second pad portion.

10. The electrochemical mechanical polishing apparatus of claim 1, wherein the electrode is provided in plural, and
the plurality of electrodes are disposed to be spaced apart from each other at an edge portion of the second pad portion in a circumferential direction of the second pad portion, and is connected to a lower surface of the second pad portion.

11. An electrochemical mechanical polishing apparatus, comprising:
a platen;
a polishing pad disposed above the platen, and including a first pad portion including a groove formed concavely inwardly on an upper surface of the first pad portion, and formed of a conductive material, and a second pad portion disposed below the first pad portion, and formed of a conductive material;
a polishing head including a retainer ring supporting a wafer and including a conductive material, and disposed on the polishing pad to press the wafer; and
an electrode disposed between the platen and the polishing pad and connected to the second pad portion.

12. The electrochemical mechanical polishing apparatus of claim 11, wherein the first pad portion and the second pad portion include glassy carbon, and
a concentration of glassy carbon included in the first pad portion is less than or equal to a concentration of glassy carbon included in the second pad portion.

13. The electrochemical mechanical polishing apparatus of claim 11, wherein the first pad portion and the second pad portion include glassy carbon, and
a concentration of glassy carbon included in the first pad portion is greater than a concentration of glassy carbon included in the second pad portion.

14. The electrochemical mechanical polishing apparatus of claim 11, wherein the first pad portion includes a first conductive region including a first concentration of glassy carbon and a second conductive region including a second concentration of glassy carbon, less than the first concentration, and
the first conductive region and the second conductive region are disposed alternately in a radial direction of the polishing pad.

15. The electrochemical mechanical polishing apparatus of claim 14, wherein the first conductive region is disposed in a central portion and an edge portion of the first pad portion, respectively, and
the second conductive region is disposed between the central portion and the edge portion of the first pad portion in the radial direction of the polishing pad.

16. The electrochemical mechanical polishing apparatus of claim 11, wherein the retainer ring is formed of a composite material including a non-conductive material and a conductive material.

17. An electrochemical mechanical polishing apparatus, comprising:
a platen;
a polishing pad disposed above the platen, and including a first pad portion including a groove formed concavely inwardly on an upper surface of the first pad portion and including a conductive material, and a second pad portion disposed below the first pad portion and including a non-conductive material;
a polishing head including a retainer ring supporting a wafer and including a conductive material, and disposed above the polishing pad to press the wafer; and
an electrode connected to the first pad portion.

18. The electrochemical mechanical polishing apparatus of claim 17, wherein the first pad portion includes a first conductive region including a first concentration of glass carbon and a second conductive region including a second concentration of glass carbon, and
the first conductive region and the second conductive region are disposed alternately in a radial direction of the polishing pad.

19. The electrochemical mechanical polishing apparatus of claim 17, wherein the electrode is connected to the upper surface of the first pad portion.

20. The electrochemical mechanical polishing apparatus of claim 17, wherein the retainer ring is formed of a composite material including a non-conductive material and a conductive material.
